(19) United States
(12) Patent Application Publication
(10) Pub. No.: US 2026/0059703 A1
(43) Pub. Date: Feb. 26, 2026

(54) WATER-PUMP-INTEGRATED WATER COOLING RADIATOR FOR COMPUTER

(71) Applicant: Garsendee Technology Co., Ltd, Dongguan (CN)

(72) Inventors: Hongming ZHU, Yueqing (CN); Zhicheng LIN, Guangzhou (CN)

(73) Assignee: Garsendee Technology Co., Ltd, Dongguan (CN)

(21) Appl. No.: 19/327,284

(22) Filed: Sep. 12, 2025

Related U.S. Application Data
(63) Continuation-in-part of application No. 18/884,415, filed on Sep. 13, 2024.

(30) Foreign Application Priority Data
Aug. 21, 2024 (CN) 202422037246.8
Jul. 1, 2025 (CN) 202510909238.4

(51) Int. Cl. H05K 7/20; F04D 1/02; F04D 13/06; F04D 29/08

(52) U.S. Cl. CPC H05K 7/20272; F04D 1/02; F04D 13/064; F04D 13/0686; F04D 29/086; H05K 7/20263

(57) ABSTRACT

A water-pump-integrated water cooling radiator for a computer includes a water tank, an impeller and a driving device. The water tank includes a first water tank and a second water tank. A plurality of tubes are arranged between the first water tank and the second water tank, and a heat dissipation fin is arranged between every two adjacent tubes. The first water tank is provided with at least two liquid chambers arranged at intervals, and two different liquid chambers are respectively connected to a water outlet and a water inlet. The impeller is pivotally mounted in one of the liquid chambers. A partition plate is provided on the first water tank at a position away from the tubes. A disk extending radially is arranged on a side wall of the impeller close to the partition plate.

### CROSS-REFERENCE TO RELATED APPLICATIONS

The present application is a continuation-in-part of U.S. patent application Ser. No. 18/884,415, filed on Sep. 13, 2024, which claims priority to Chinese Patent Application No. 202422037246.8, filed on Aug. 21, 2024. The present application also claims priority to Chinese Patent Application No. 202510909238.4, filed on Jul. 1, 2025. All of the aforementioned applications are incorporated herein by reference in their entireties.

### TECHNICAL FIELD

The present disclosure relates to the technical field of water cooling radiators, and in particular to a water-pump-integrated water cooling radiator for a computer.

### BACKGROUND

The existing computer heat exchanger, also known as a water cooling radiator, realizes heat exchange between a heated liquid and the outside through radiating fins by cooperation between the tubes and the radiating fins (or a fan).

In the existing design, the water tank, the tubes and the water pump are integrated. However, due to the large size of the water pump, the size of the water tank is reduced accordingly. Therefore, in order to increase the volume of the water tank (that is, to store more liquid), the overall structure is complicated accordingly. For example, in Chinese Patent Publication CN215867735U, in order to make the stator and the rotor work cooperatively, a concave-convex structure is designed, so that the impeller is located in the water chamber, and the contact between electronic elements and the water chamber is avoided. However, the production cost of the mold is high, and the overall size of the water pump is also large due to a large thickness.

### SUMMARY

The main objective of the present disclosure is to provide a water-pump-integrated water cooling radiator for a computer, in order to improve the structure of the water cooling radiator and reduce the size of the structure of the water pump. Moreover, the predetermined volume of the water tank can be ensured due to a small thickness. In addition, the structure is simple, and the production cost is effectively reduced.

In order to achieve the above objective, the present disclosure provides a water-pump-integrated water cooling radiator for a computer, including:
a water tank, wherein the water tanks includes a first water tank and a second water tank, a plurality of tubes are arranged between the first water tank and the second water tank, and a heat dissipation fin is arranged between every two adjacent ones of the tubes;
the first water tank is provided with at least two liquid chambers arranged at intervals, and two different ones of the liquid chambers are respectively connected to a water outlet and a water inlet;
an impeller, wherein the impeller is pivotally mounted in one of the liquid chambers, a partition plate is provided on the first water tank at a position away from the tubes, a disk is arranged on a side wall of the impeller close to the partition plate, and the disk extends radially from the impeller;
a driving device, wherein the driving device includes a stator arranged on an outer wall of the partition plate and a rotor cooperating with the stator, the rotor and the stator are radially arranged, the rotor is located at a side wall of the stator, and magnetic fields of the stator and the rotor are axially tangent to each other; and
the rotor is arranged on the disk, or the rotor drives the disk to rotate through an intermediate member; and when the impeller rotates, the impeller is arranged to drive liquid to flow.

In actual operation, there may be one or two driving devices provided, that is, the driving device may be mounted at any one of the liquid chambers, or the driving devices may be mounted at both of the two liquid chambers.

When the impeller rotates, the liquid passes through the water inlet, the first liquid chamber, the tubes, the second water tank, the second liquid chamber (the driving device is arranged at the second liquid chamber; certainly, the driving devices may be mounted at both of the two liquid chambers, and in this case, the directions of the water inlet and the water outlet can be ignored) and the water outlet in sequence, thereby realizing heat exchange of the heated liquid. Then, the cooled liquid is delivered to heating elements through the water outlet, thereby realizing cooling. The first liquid chamber refers to the liquid chamber connected to the water inlet, and the second liquid chamber refers to the liquid chamber connected to the water outlet.

The liquid chambers and the outer wall of the first water tank are independent of each other, so the liquid does not affect the circuit elements, thereby ensuring the service life and safety of the driving device.

The stator and the rotor are radially arranged, so that the stator and the rotor can be axially tangent, and the overall thickness of the driving device can be reduced. Moreover, the first water tank and the water pump are integrally designed, so that the structure is simpler and the size is smaller, thereby improving aesthetics of the computer water cooling structure.

The structure is simpler. No concave-convex structure is needed between the water chamber and the pump chamber to realize the tangency between the stator and the rotor, and the use of the radial structure is adequate. Therefore, the production cost of the mold is lower, and the market competitiveness is effectively improved.

In the case of the same output torque, rotational speed and power, compared with a radial flux motor, the axial flux motor (i.e. the driving device of the present disclosure) is more suitable for occasions having high requirements for space due to the reduction of the axial size by 50% or above, and can improve maneuverability of equipment and realize light weight due to the reduction of the weight by about 50%.

The direction in which the pump base is arranged can be vertical or radial, so the corresponding direction can also be changed accordingly.

### BRIEF DESCRIPTION OF THE DRAWINGS

FIG. 1 is a sectional view of a water-pump-integrated water cooling radiator for a computer.

FIG. 2 is a schematic view of the water-pump-integrated water cooling radiator for a computer.

FIG. 3 is an exploded view I of the present disclosure.

FIG. 4 is a schematic view of a first embodiment.

FIG. 5 is a schematic view of a second embodiment.

FIG. 6 is a schematic view of the present disclosure.

FIG. 7 is a schematic partial enlarged view.

FIG. 8 is a schematic view of a stator and a rotor in cooperation.

FIG. 9 is a schematic three-dimensional view of a new embodiment.

FIG. 10 is an exploded view I of the new embodiment.

FIG. 11 is an exploded view II of the new embodiment.

FIG. 12 is a schematic view of a rotating shaft of the new embodiment.

FIG. 13 is a sectional view of a flow guide cavity of the new embodiment.

FIG. 14 is a sectional view of a water outlet of the new embodiment.

### DETAILED DESCRIPTION OF THE EMBODIMENTS

The technical solutions in the embodiments of the present disclosure will be clearly and completely described below with reference to the accompanying drawings. It is apparent that the described embodiments are only a part of the embodiments, rather than all of the embodiments of the present disclosure. All other embodiments obtained by those of ordinary skill in the art based on the embodiments in the present disclosure without creative work are within the protection scope of the present disclosure.

It should be noted that if there are directional indications (such as up, down, left, right, front, rear, top, bottom, inside, outside, vertical, horizontal, longitudinal, counterclockwise, clockwise, circumferential, radial, axial, etc.) in the embodiments of the present disclosure, the directional indications are only used to explain the relative position relationship and movement between components in a certain posture (as shown in the accompanying drawings). If this certain posture changes, the directional indications also change accordingly.

In addition, if there is a description of “first” or “second” in the embodiments of the present disclosure, the description of “first” or “second” is only for descriptive purposes, and cannot be understood as indicating or implying its relative importance or implicitly indicating the number of indicated technical features. Therefore, a feature defined by “first” or “second” may explicitly indicate or implicitly include at least one of such features. In addition, the technical solutions of the embodiments may be combined with each other, which must be based on the fact that those of ordinary skill in the art are able to realize it. When the combination of technical solutions is contradictory or impossible to realize, it should be considered that this combination of technical solutions does not exist and is not within the scope of protection of the present disclosure.

In the present disclosure, pivotal mounting refers to a mounting manner that realizes a rotatable connection between components through a pivot or a similar structure, and its core lies in allowing the connected components to rotate relatively around a fixed axis.

In the present disclosure, “magnetic fields of the stator and the rotor are axially tangent to each other” means that the magnetic field of the stator and the magnetic field of the rotor form an axially tangential relationship in spatial distribution, that is, the magnetic fields of the stator and the rotor are perpendicular to each other in the axial direction or intersect at a specific angle, thus generating tangential electromagnetic force to drive the rotor to rotate.

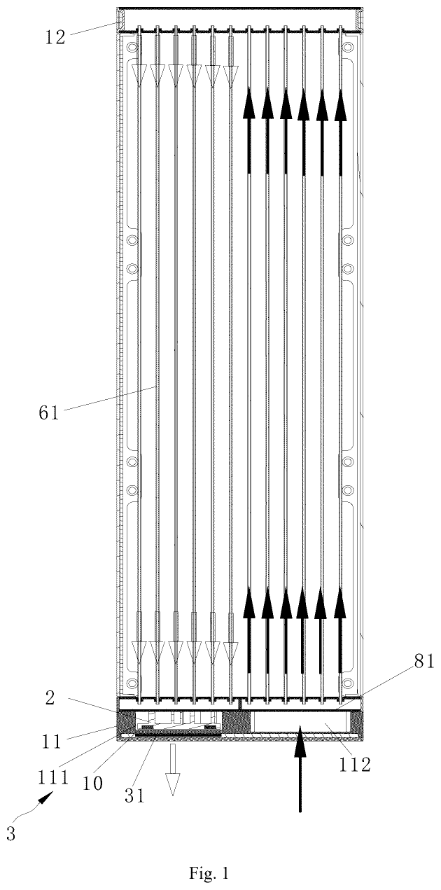

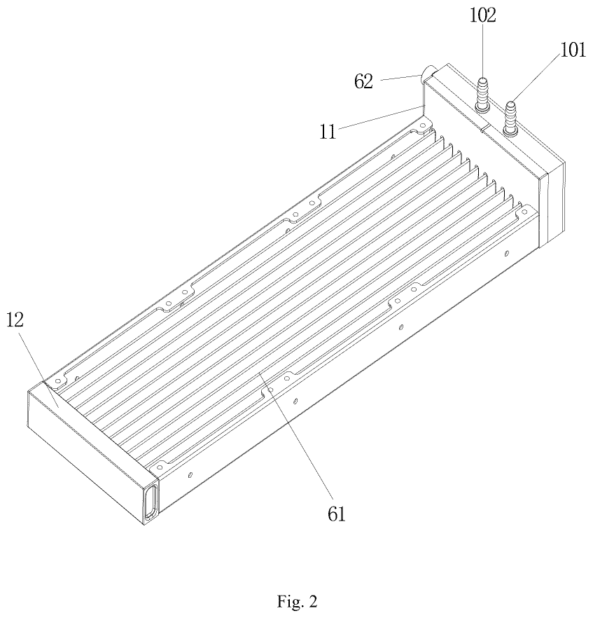

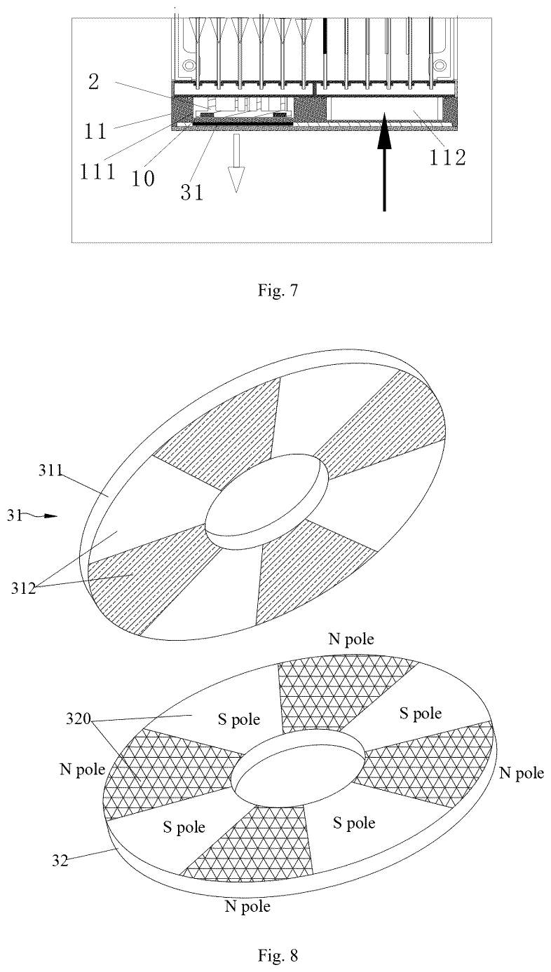

As shown in FIG. 1, FIG. 2 and FIG. 7, a water-pump-integrated water cooling radiator for a computer includes: a water tank, an impeller 2 and a driving device 3.

The water tank includes a first water tank 11 and a second water tank 12. A plurality of tubes 61 are arranged between the first water tank 11 and the second water tank 12, and a heat dissipation fin is arranged between every two adjacent ones of the tubes 61.

The first water tank 11 is provided with at least two liquid chambers arranged at intervals, and the two different liquid chambers are respectively connected to a water outlet 101 and a water inlet 102. The liquid chamber connected to the water inlet is named a first liquid chamber 111, and the liquid chamber connected to the water outlet is named a second liquid chamber 112.

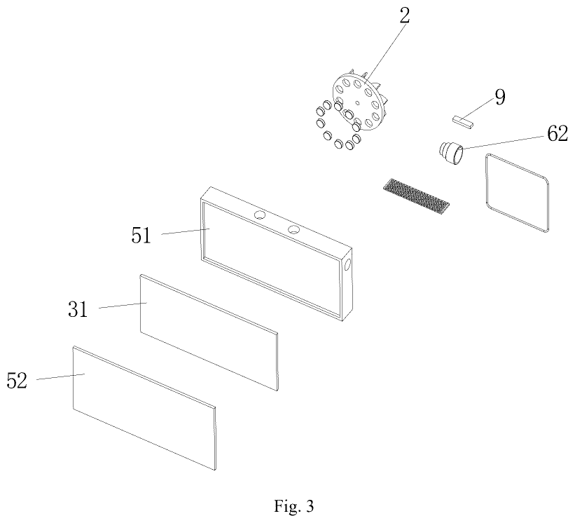

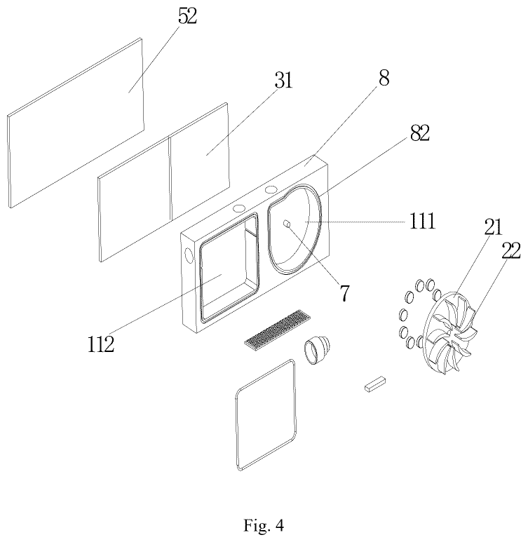

The impeller 2 is pivotally mounted in one of the liquid chambers, and a partition plate 10 is provided on the first water tank 11 at a position away from the tubes 61. Referring to FIG. 3 and FIG. 4, a disk 21 is arranged on a side wall of the impeller 2 close to the partition plate 10, and the disk 21 extends radially from the impeller 2.

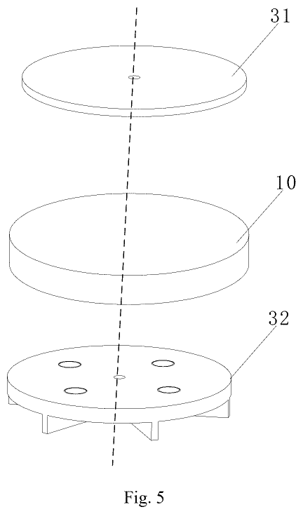

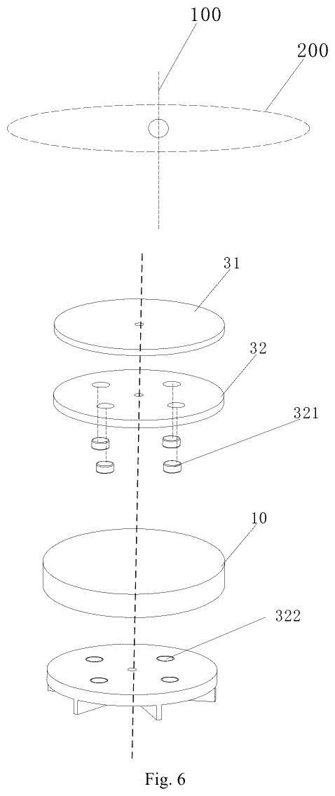

As shown in FIG. 5 and FIG. 6, the driving device 3 includes a stator 31 arranged on an outer wall of the partition plate 10 and a rotor 32. The rotor 32 cooperates with the stator 31. The rotor 32 and the stator 31 are radially arranged. The rotor 32 is located at a side wall of the stator 31. Magnetic fields of the stator 31 and the rotor 32 are axially tangent to each other.

The rotor 32 is arranged on the disk 21, or the rotor 32 drives the disk 21 to rotate through an intermediate member. When the impeller 2 rotates, the impeller 2 is arranged to drive liquid to flow.

In actual operation, there may be one or two driving devices 3 provided, that is, the driving device 3 may be arranged at any one of the liquid chambers, or the driving devices 3 may be mounted at both of the two liquid chambers.

When the impeller 2 rotates, the liquid passes through the water inlet 102, the first liquid chamber 111, the tubes 61, the second water tank 12, the second liquid chamber 112 (the driving device 3 is arranged at the second liquid chamber 112) and the water outlet 101 in sequence, thereby realizing heat exchange of the heated liquid. Then, the cooled liquid is delivered to heating elements through the water outlet, thereby realizing cooling.

The liquid chambers and the outer wall of the first water tank 11 are independent of each other, so the liquid does not affect the circuit elements, thereby ensuring the service life and safety of the driving device 3.

The stator 31 and the rotor 32 are radially arranged, so that the stator and the rotor can be axially tangent, and the overall thickness of the driving device 3 can be reduced. Moreover, the first water tank 11 and the water pump are integrally designed, so that the structure is simpler and the size is smaller, thereby improving aesthetics of the computer water cooling structure.

The structure is simpler. No concave-convex structure is needed between the water chamber and the pump chamber to realize the tangency between the stator 31 and the rotor 32, and the use of the radial structure is adequate. Therefore, the production cost of the mold is lower, and the market competitiveness is effectively improved.

In the case of the same output torque, rotational speed and power, compared with a radial flux motor, the axial flux motor (i.e. the driving device 3 of the present disclosure) is more suitable for occasions having high requirements for space due to the reduction of the axial size by 50% or above, and can improve maneuverability of equipment and realize light weight due to the reduction of the weight by about 50%.

The direction in which the pump base is arranged can be vertical or radial, so the corresponding direction can also be changed accordingly.

Based on one or more of the above embodiments, as a preferred embodiment, referring to FIG. 6, the stator 31 includes a bracket 311 and magnetic induction coils 312 arranged on the bracket 311 at intervals, and a magnetic induction direction of each one of the magnetic induction coils 312 is an axial direction 100. The axial direction 100 is perpendicular to a radial direction 200.

The rotor 32 is provided with a plurality of permanent magnets 320. For the structure, reference can be referred to an axial flux motor. By controlling the direction of the current, the rotation of the rotor 32 is further controlled.

In a first embodiment, when the permanent magnets 320 are arranged on the disk 21, the stator 31 directly drives the permanent magnets 320, thereby driving the impeller 2 to rotate, and the partition plate 10 is arranged between the stator 31 and the rotor 32. In this structure, the air gap is removed, thus alleviating the problem of unstable heat dissipation of the axial flux motor. That is, the rotor 32 is located in the liquid chamber, so that heat can be fully dissipated. In principle, the magnetic field of the permanent magnets 320 is stable, so the component that is damaged in most cases is the stator 31 (that is, the magnetic induction coils 312). Therefore, even if the cooling component is damaged, the stator 31 can be replaced, which effectively improves the convenience of maintenance. The rotor 32 and the disk 21 may be integrally injection-molded, thereby effectively protecting the structure of the stator 31 and improving the stability of the permanent magnets 320.

Based on one or more of the above embodiments, as a preferred embodiment, projected areas of the stator 31 and the rotor 32 in the axial direction are substantially the same, thereby ensuring the stability of driving and avoiding loss of the magnetic fields. Each one of the permanent magnets 320 is fan-shaped, and the permanent magnets 320 are annularly distributed on the rotor 32. Each one of the permanent magnets 320 includes a South (S) pole and a North (N) pole, and the S pole of one of the permanent magnets and the N pole of another adjacent one of the permanent magnets face the same side, thus realizing the tangency of the magnetic fields. For example, the permanent magnet a and the permanent magnet b are arranged adjacent to each other. The S pole of the permanent magnet a and the N pole of the permanent magnet b face a first side, and the N pole of the permanent magnet a and the S pole of the permanent magnet b facing a second side. The first side is opposite to the second side.

The partition plate 10 has a planar structure.

“Projected areas of two objects are substantially the same” means that the projected areas of the two objects are exactly the same, or an absolute value of a difference between the projected areas of the two objects is less than a preset value.

In a second embodiment, referring to FIG. 6, the rotor 32 is pivotally mounted between the stator 31 and the partition plate 10. A lower wall of the rotor 32 is provided with a first magnetic member 321, and the disk 21 is provided with a second magnetic member 322 cooperating with the first magnetic member 321. The partition plate is arranged between the rotor 32 and the disk 21. Generally speaking, the rotor 32 is also provided with a structure such as a core to fix the permanent magnets 320. When the permanent magnets 320 are integrally injection-molded, the use of the core can be reduced because magnetic poles of the permanent magnets can be fixed.

Based on one or more of the above embodiments, as a preferred embodiment, the driving device 3 is a single module, and the driving device 3 is mounted on the outer wall of the partition plate 10, thus facilitating the maintenance of the driving device 3. Theoretically, the permanent magnets 320 of the impeller 2 can never be damaged, so the rotation of the impeller 2 can be realized by replacing the driving device 3.

Based on one or more of the above embodiments, as a preferred embodiment, the driving device 3 is arranged on a pump housing, and the pump housing is fixed to the first water tank 11 through screws. Certainly, a snap-fit structure may also be used for mounting and fixation.

Based on one or more of the above embodiments, as a preferred embodiment, the impeller 2 includes blades 22 arranged on a lower wall of the disk 21, and the blades 22 are circumferentially distributed along a peripheral wall or a side wall of the disk 21. Specifically, the blades 22 may be arc-shaped, strip-shaped or curved-shaped structures, so as to realize the flow of the liquid in a predetermined direction.

Specifically, referring to FIG. 4, a side wall of the partition plate 10 extends toward the liquid chamber to form a first rotating shaft 7. The first rotating shaft 7 is configured to mount the impeller 2. The first rotating shaft 7 extends along both sides or one side of the liquid chamber, that is, the impeller 2 may be a biaxial structure or a uniaxial structure, thereby ensuring the rotation stability and the rotation concentricity of the impeller 2.

A bearing is arranged between the first rotating shaft 7 and the impeller 2. The bearing may be a corrosion-resistant structure such as a ceramic bearing, thereby improving the use stability.

Based on one or more of the above embodiments, as a preferred embodiment, the partition plate 10 extends to form a pivot portion. The pivot portion is configured to mount the rotor 32 so as to rotate the rotor 32. Certainly, for the rotor 32 with a disk structure, the pivot portion may also be a bearing arranged on an outer side of the rotor 32; or a second rotating shaft arranged in a middle of the rotor 32; or bearings arranged on inner and outer sides of the device.

Specifically, referring to FIG. 3, the liquid chamber is provided with a sensor 9. The sensor may detect a liquid temperature, liquid quality, a liquid pressure and a liquid level of the liquid in the liquid chamber. The sensor is connected to a control device. The control device is also connected to the driving device 3. The control device may control a rotational speed of the impeller 2 according to data of the sensor.

Specifically, as shown in FIG. 1 and FIG. 7, the liquid chambers include the first liquid chamber 111 and the second liquid chamber 112, and the first liquid chamber 111 and/or the second liquid chamber 112 are/is provided with the driving devices/device 3.

Specifically, the liquid chamber provided with the driving device 3 has a circular cross section, so that the liquid can flow in a predetermined direction.

Specifically, as shown in FIG. 2, the water inlet 102 and the water outlet 101 are provided in an upper wall and/or a side wall of the first water tank 11.

Specifically, the second liquid chamber 112 is not provided with the driving device 3, and the second liquid chamber 112 is provided with the partition plate 10 between the fluid inlet and the tubes 61. The partition plate 10 is provided with a filter layer. The filter layer can remove impurities generated by copper-aluminum reaction in the liquid, so that the impurities will not completely accumulate in the water channel, thereby avoiding performance degradation caused by blocking of the water channel.

Moreover, impurities during the refill of the liquid can be removed, thereby effectively improving the flow smoothness of the fluid.

Specifically, referring to FIG. 8, the bracket 311 is a (Printed Circuit Board) PCB or a core, and the magnetic induction coils 312 are arranged on the PCB.

In actual design, the magnetic induction coils 312 are preferably wound on the PCB, which is convenient for circuit control and has a smaller thickness.

Specifically, as shown in FIG. 3, when the bracket 311 is a PCB, the side wall of the first water tank 11 is provided with a recess 51. The PCB is arranged in the recess 51, and a side of the recess 51 away from the PCB is also provided with a rear cover 52 (i.e., the pump housing). This facilitates the mounting of the stator 31. Moreover, according to actual needs, a structure that is adapted to the first water tank 11 in length or a structure that can cooperate with the first liquid chamber 111 may be provided, thereby realizing modular production of the driving device 3.

Specifically, as shown in FIG. 1 and FIG. 4, the first water tank 11 includes a positioning plate 81 and a main body 8 detachably mounted on the positioning plate 81. The main body 8 is provided with the liquid chambers, and a peripheral wall of the liquid chamber is provided with a clamping groove 82. The clamping groove is provided with a sealing ring. The positioning plate 81 is connected to ends of the tubes 61, which makes the mounting easier.

Specifically, there are two groups of tubes 61, and each group of tubes 61 has a plurality of individual tubes 61. The two groups of tubes 61 are respectively water inlet tubes and water outlet tubes. Two ends of the water inlet tube are respectively connected to the second liquid chamber 112 and the second water tank 12, and two ends of the water outlet tube are respectively connected to the first liquid chamber 111 and the second water tank 12.

Specifically, the second liquid chamber 112 is provided with a through hole. The through hole is configured to mount a refill tube 62, so as to facilitate the addition or replacement of the liquid.

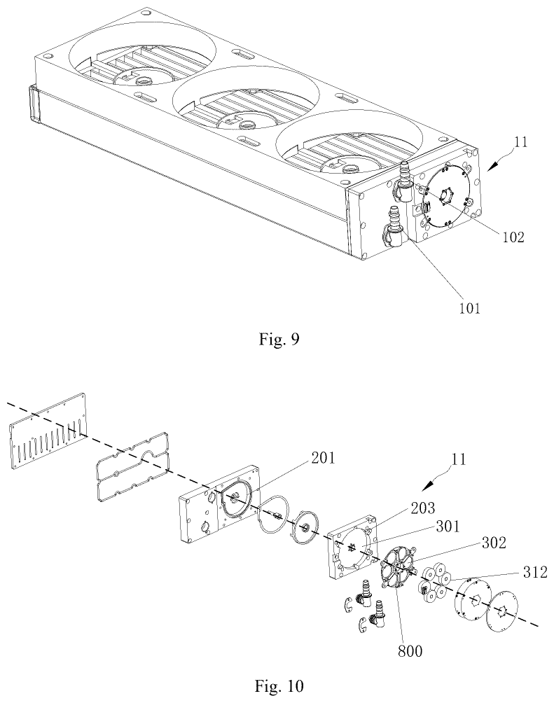

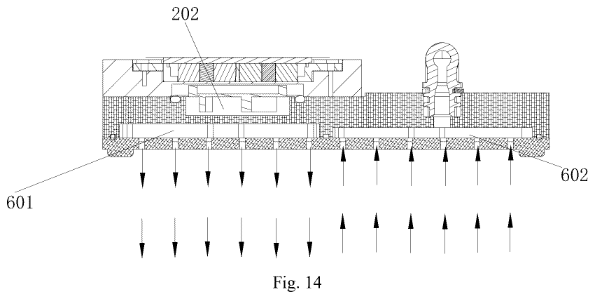

Please refer to FIG. 9, FIG. 10 and FIG. 14. Specifically, a front wall of the first water tank 11 is provided with a pivot groove 201.

A front wall of a pivot cavity 202 is provided with a cover plate 203, and the cover plate 203 and the pivot groove 201 enclose the pivot cavity 202.

The impeller 2 is pivotally mounted in the pivot cavity 202.

A front wall of the cover plate 203 is provided with magnetic induction coils, which facilitates the mounting and assembly of the impeller 2 and the magnetic induction coils, and facilitates the maintenance when a breakdown occurs. There is no need to remove the whole first water tank.

The partition plate 10 includes the cover plate 203.

Specifically, the front wall of the cover plate 203 is provided with a limiting groove 301. The limiting groove 301 is provided with positioning grooves 302 arranged at intervals, and the positioning grooves 302 are configured to mount the magnetic induction coils, thereby effectively reducing the overall thickness of the water tank and improving the integrated design of the computer system.

Based on one or more of the above embodiments, as a preferred embodiment, referring to FIG. 12, shaft grooves 400 are respectively arranged between the front wall of the first water tank 11 and a rear wall of the cover plate 203. The impeller 2 is provided with a rotating shaft 401, and two ends of the rotating shaft 401 are clamped in the shaft grooves 400, thereby effectively improving the rotation stability of the impeller 2.

Based on one or more of the above embodiments, as a preferred embodiment, the positioning grooves 302 are circumferentially distributed at intervals along a same axis.

Based on one or more of the above embodiments, as a preferred embodiment, the magnetic induction coils are connected to a control device via a PCB, or the magnetic induction coils are connected to the control device via cables.

Based on one or more of the above embodiments, as a preferred embodiment, the magnetic induction coils are independent modules, and each one of the magnetic induction coils is composed of a copper wire having a predetermined thickness wound into a coil.

Different from the existing design, the magnetic induction coils are directly mounted in the positioning grooves 302 as independent individuals, so that the inductance of the magnetic induction coils can be higher, thereby realizing a larger and higher driving force, providing a larger rotational speed when the permanent magnet and the magnetic induction coil are tangent, and improving the stability of the equipment.

Based on one or more of the above embodiments, as a preferred embodiment, the magnetic induction coils are magnetic levitation coils.

When the plurality of circumferentially distributed magnetic induction coils are energized in a predetermined sequence, the permanent magnets can be driven.

Further, the rotation of the impeller can be realized. The direction of rotation is related to the frequency of energization and the inductance.

The magnetic induction coils may be connected to the control device in series or parallel.

Based on one or more of the above embodiments, as a preferred embodiment, the control device is configured to control the plurality of magnetic induction coils to be energized in a predetermined sequence and/or in a predetermined direction.

For example, when the cables are used, independent ports may be used to be connected to the control device respectively,

When the PCB is used, the magnetic induction coils may be soldered to the PCB and then mounted in the positioning grooves 302, thereby realizing mounting and fixation of the magnetic induction coils.

For example, the PCB is directly mounted through screws.

When the fixation is realized without a PCB, the magnetic induction coils may also be fixed through a positioning cover plate.

Specifically, the magnetic induction coils are independent modules, and each one of the magnetic induction coils is composed of a copper wire having a predetermined thickness wound into a coil.

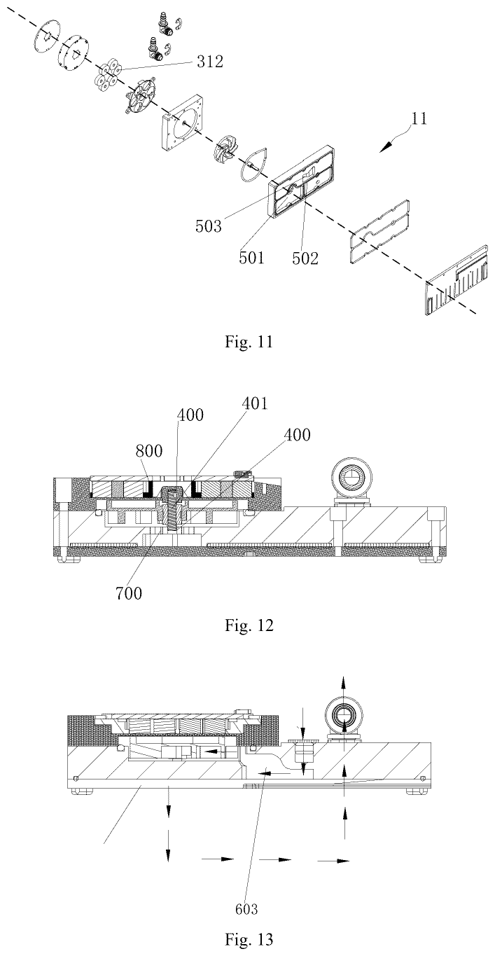

Based on one or more of the above embodiments, as a preferred embodiment, referring to FIG. 9, FIG. 11, FIG. 13 and FIG. 14, a rear wall of the first water tank 11 is provided with a first cavity groove 501, a second cavity groove 502 and a third cavity groove 503.

The rear wall of the first water tank 11 is provided with a sealing plate, and the sealing plate encloses the first cavity groove 501, the second cavity groove 502 and the third cavity groove 503 to form a first water inlet cavity 601, a first water outlet cavity 602 and a flow guide cavity 603.

One end of the flow guide cavity 603 is in communication with the water inlet 102.

Another end of the flow guide cavity 603 is in communication with the pivot cavity 202.

Referring to FIG. 12 and FIG. 14, the pivot cavity 202 is provided with a delivery channel 700 in communication with the first water inlet cavity 601.

Based on one or more of the above embodiments, as a preferred embodiment, as shown in FIG. 10 and FIG. 12, the magnetic induction coils 312 are arranged on the bracket 800. The bracket 800 is provided with the positioning grooves 302, and the bracket 800 is detachably mounted in the limiting groove 301, thereby realizing modular mounting of the magnetic induction coils.

Based on one or more of the above embodiments, as a preferred embodiment, the limiting groove 301 is further provided with an outer cover, thereby realizing the relative sealing of the limiting groove 301.

The above only describes the preferred embodiments of the present disclosure, and is not intended to limit the scope of the present disclosure. Under the inventive concept of the present disclosure, any equivalent structural changes made by using the contents of the specification and accompanying drawings of the present disclosure, or any direct/indirect applications in other related technical fields are included within the scope of protection of the present disclosure.

What is claimed is:

1. A water-pump-integrated water cooling radiator for a computer, comprising:
a water tank, wherein the water tank comprises a first water tank and a second water tank, a plurality of tubes are arranged between the first water tank and the second water tank, and a heat dissipation fin is arranged between every two adjacent tubes; the first water tank is provided with at least two liquid chambers arranged at intervals, and two different liquid chambers are respectively connected to a water outlet and a water inlet;
an impeller, wherein the impeller is pivotally mounted in one of the liquid chambers, a partition plate is provided on the first water tank at a position away from the tubes, a disk is arranged on a side wall of the impeller close to the partition plate, and the disk extends radially from the impeller; and
a driving device, wherein the driving device comprises a stator arranged on an outer wall of the partition plate and a rotor, the rotor cooperates with the stator, the rotor and the stator are radially arranged, the rotor is located at a side wall of the stator, and magnetic fields of the stator and the rotor are axially tangent to each other; wherein,
the rotor is arranged on the disk, or the rotor drives the disk to rotate through an intermediate member; and when the impeller rotates, the impeller is arranged to drive liquid to flow;
a front wall of the first water tank is provided with a pivot groove;
a front wall of a pivot cavity is provided with a cover plate, and the cover plate and the pivot groove enclose the pivot cavity;
the impeller is pivotally mounted in the pivot cavity;
a front wall of the cover plate is provided with magnetic induction coils; and
the front wall of the cover plate is provided with a limiting groove, the limiting groove is provided with positioning grooves arranged at intervals, and the positioning grooves are configured to mount the magnetic induction coils.

2. The water-pump-integrated water cooling radiator for the computer according to claim 1, wherein the stator comprises a bracket and the magnetic induction coils arranged on the bracket at intervals, and a magnetic induction direction of each one of the magnetic induction coils is an axial direction; and
the rotor is provided with a plurality of permanent magnets.

3. The water-pump-integrated water cooling radiator for the computer according to claim 2, wherein when the permanent magnets are arranged on the disk, the stator directly drives the permanent magnets, thereby driving the impeller to rotate, and the partition plate is arranged between the stator and the rotor.

4. The water-pump-integrated water cooling radiator for the computer according to claim 2, wherein projected areas of the stator and the rotor in the axial direction are substantially the same;
each one of the permanent magnets is fan-shaped, and the permanent magnets are distributed on the rotor; each one of the permanent magnets includes a South (S) pole and a North (N) pole, and the S pole of one of the permanent magnets and the N pole of an adjacent one of the permanent magnets face the same side; and the partition plate has a planar structure.

5. The water-pump-integrated water cooling radiator for the computer according to claim 2, wherein the rotor is pivotally mounted between the stator and the partition plate; and
a lower wall of the rotor is provided with a first magnetic member, the disk is provided with a second magnetic member cooperating with the first magnetic member, and the partition plate is arranged between the rotor and the disk.

6. The water-pump-integrated water cooling radiator for the computer according to claim 1, wherein the driving device is a single module, and the driving device is mounted on the outer wall of the partition plate.

7. The water-pump-integrated water cooling radiator for the computer according to claim 1, wherein the driving device is arranged on a pump housing, and the pump housing is fixed to the first water tank through screws.

8. The water-pump-integrated water cooling radiator for the computer according to claim 1, wherein the impeller comprises blades arranged on a lower wall of the disk, and the blades are circumferentially distributed along a peripheral wall or a side wall of the disk.

9. The water-pump-integrated water cooling radiator for the computer according to claim 1, wherein the partition plate extends to form a pivot portion; and the pivot portion is configured to mount the rotor so as to rotate the rotor.

10. The water-pump-integrated water cooling radiator for the computer according to claim 1, wherein shaft grooves are arranged between the front wall of the first water tank and a rear wall of the cover plate, the impeller is provided with a rotating shaft, and two ends of the rotating shaft are clamped in the shaft grooves.

11. The water-pump-integrated water cooling radiator for the computer according to claim 10, wherein the positioning grooves are circumferentially distributed at intervals along a same axis.

12. The water-pump-integrated water cooling radiator for the computer according to claim 1, wherein the magnetic induction coils are connected to a control device via a Printed Circuit Board (PCB), or the magnetic induction coils are connected to the control device via cables.

13. The water-pump-integrated water cooling radiator for the computer according to claim 1, wherein the magnetic induction coils are independent modules, and each one of the magnetic induction coils is composed of a copper wire having a predetermined thickness wound into a coil.

14. The water-pump-integrated water cooling radiator for the computer according to claim 12, wherein the magnetic induction coils are magnetic levitation coils.

15. The water-pump-integrated water cooling radiator for the computer according to claim 12, wherein the control device is configured to control the plurality of magnetic induction coils to be energized in a predetermined sequence and/or in a predetermined direction; and the magnetic induction coils are independent modules, and each one of the magnetic induction coils is composed of a copper wire having a predetermined thickness wound into a coil.

16. The water-pump-integrated water cooling radiator for the computer according to claim 12, wherein a rear wall of the first water tank is provided with a first cavity groove, a second cavity groove and a third cavity groove;
the rear wall of the first water tank is provided with a sealing plate, and the sealing plate encloses the first cavity groove, the second cavity groove and the third cavity groove to form a first water inlet cavity, a first water outlet cavity and a flow guide cavity;
one end of the flow guide cavity is in communication with the water inlet;
another end of the flow guide cavity is in communication with the pivot cavity; and
the pivot cavity is provided with a delivery channel in communication with the first water inlet cavity.

17. The water-pump-integrated water cooling radiator for the computer according to claim 1, wherein the magnetic induction coils are arranged on the bracket, the bracket is provided with the positioning grooves, and the bracket is detachably mounted in the limiting groove.

18. The water-pump-integrated water cooling radiator for the computer according to claim 1, wherein the limiting groove is further provided with an outer cover.
